(19) United States
(12) Patent Application Publication
(10) Pub. No.: US 2021/0367207 A1
(43) Pub. Date: Nov. 25, 2021

(54) DISPLAY PANEL AND METHOD OF FABRICATING THEREOF

(71) Applicant: Wuhan China Star Optoelectronics Semiconductor Display Technology Co., Ltd., Wuhan (CN)

(72) Inventor: Xingyong ZHANG, Wuhan (CN)

(73) Assignee: Wuhan China Star Optoelectronics Semiconductor Display Technology Co., Ltd., Wuhan (CN)

(21) Appl. No.: 16/632,924

(22) PCT Filed: Oct. 28, 2019
(86) PCT No.: PCT/CN2019/113549

§ 371 Date: Jan. 22, 2020

(30) Foreign Application Priority Data
May 27, 2019 (CN) 201910447752.5

(51) Int. Cl. H01L 51/52; H01L 51/56

(52) U.S. Cl. CPC H01L 51/5253; H01L 27/3244; H01L 51/56

(57) ABSTRACT

A display panel and a method of fabricating thereof. The display panel comprising a display area and a barrier wall surrounding the display area, wherein a top of the barrier wall has a plurality of groove structures arranged in parallel, an extending direction of the plurality of groove structures is parallel to an extending direction of the barrier wall.

### BACKGROUND OF INVENTION

### Field of Invention

The present invention relates to the field of electronic display, and in particular, to a display panel and method of fabricating thereof.

### Description of Prior Art

The organic light emitting diode (OLED) display panels in prior art usually adopt thin film encapsulation structures to achieve sealing of display area. The thin film encapsulation structures have low cost and good sealing effect, thereby are widely used in OLED display panels.

### Technical Problems

A thin film encapsulation structure typically includes at least one organic barrier layer. The organic barrier layer has fluidity, so it is necessary to provide a plurality of barrier walls on a periphery of the display area of the display panel to improve an encapsulation effect by preventing the organic barrier layer from overflowing. The presence of the barrier wall increases the area of a non-display area. In order to increase a screen ratio of the display panel, it is necessary to reduce the number of barrier walls while ensuring the barrier effect of the barrier wall as much as possible to reduce the area occupied by the barrier walls.

### SUMMARY OF INVENTION

The present application provides a display panel and a manufacturing method thereof, which can effectively reduce the area occupied by barrier walls.

In order to solve the above problems, the present application provides a display panel comprising a display area and a barrier wall surrounding the display area, wherein a top of the barrier wall has a plurality of groove structures arranged in parallel, an extending direction of the plurality of groove structures is parallel to an extending direction of the barrier wall;

wherein the barrier wall further comprises a plurality of cap structures located on the top of the barrier wall on both sides of the plurality of groove structures;

wherein depths of the plurality of groove structures are greater than or equal to a quarter of a height of the barrier wall, heights of the cap structures are less than or equal to a minimum depth of the groove structure;

wherein the groove structures have different depths, the cap structures have different heights;

wherein a depth of each groove structure is positively related to a distance from the groove structure to the display area, a depth of the groove structure closest to the display area is less than a depth of the groove structure furthest from the display area.

According to one aspect of the application, wherein the barrier wall comprises:

a first section comprising a plurality of first subsections extending along a length direction of the plurality of first sections, wherein first intervals are disposed between two adjacent first subsections;

a second section disposed in parallel with the first section, wherein the second section comprises a plurality of second subsections, second intervals are disposed between two adjacent second subsections, positions of the second subsections correspond to positions of the first intervals, positions of first subsections correspond to positions of the second intervals; and

a plurality of connecting sections located between the first section and the second section, wherein the connecting sections are used for connecting each of the first subsections and the two second subsections adjacent to the first subsection.

According to one aspect of the application, wherein the plurality of first subsections are equal in length, the plurality of first intervals are equal in length, the plurality of second subsections are equal in length, the plurality of second intervals are equal in length.

According to one aspect of the application, wherein the length of the plurality of first subsections is greater than the length of the plurality of second intervals, the length of the plurality of second subsections is greater than the length of the first interval.

According to one aspect of the application, wherein a distance between the first section and the second section is greater than or equal to a sum of the widths of the first section and the second section and less than or equal to twice the sum of the widths of the first section and the second section.

The present application further provides a display panel comprising a display area and a barrier wall surrounding the display area, wherein a top of the barrier wall has a plurality of groove structures arranged in parallel, an extending direction of the plurality of groove structures is parallel to an extending direction of the barrier wall.

According to one aspect of the application, wherein the barrier wall further comprises a plurality of cap structures located on top of the barrier wall on both sides of the plurality of groove structures.

According to one aspect of the application, wherein depths of the plurality of groove structures are greater than or equal to a quarter of a height of the barrier wall, heights of the cap structures are less than or equal to a minimum depth of the groove structure.

According to one aspect of the application, wherein the groove structures have different depths, the cap structures have different heights.

According to one aspect of the application, wherein a depth of each groove structure is positively related to a distance from the groove structure to the display area, a depth of the groove structure closest to the display area is less than a depth of the groove structure furthest from the display area.

According to one aspect of the application, wherein the barrier wall comprises:

a first section comprising a plurality of first subsections extending along a length direction of the plurality of first sections, wherein first intervals are disposed between two adjacent first subsections;

a second section disposed in parallel with the first section, wherein the second section comprises a plurality of second subsections, second intervals are disposed between two adjacent second subsections, positions of the second subsections correspond to positions of the first intervals, positions of first subsections correspond to positions of the second intervals; and

a plurality of connecting sections located between the first section and the second section, wherein the connecting sections are used for connecting each of the first subsections and the two second subsections adjacent to the first subsection.

According to one aspect of the application, wherein the plurality of first subsections are equal in length, the plurality of first intervals are equal in length, the plurality of second subsections are equal in length, the plurality of second intervals are equal in length.

According to one aspect of the application, wherein the length of the plurality of first subsections is greater than the length of the plurality of second intervals, the length of the plurality of second subsections is greater than the length of the first interval.

According to one aspect of the application, wherein a distance between the first section and the second section is greater than or equal to a sum of the widths of the first section and the second section and less than or equal to twice the sum of the widths of the first section and the second section.

The present application further provides a method of fabricating a display panel, wherein the method comprises the steps of:

providing a substrate and forming a display area on the substrate;

forming a barrier wall surrounding the display area;

forming a first insulating layer on a top of the barrier wall;

patterning the first insulating layer to form a plurality of cap structures arranged in parallel, an extending direction of the plurality of cap structures is parallel to an extending direction of the barrier wall;

etching the barrier wall by using the cap structures as a mask to form a plurality of parallel groove structures.

### Beneficial Effects

The present application improves a barrier capability of a single barrier wall to the organic encapsulation layer by providing a plurality of groove structures on the top of the barrier wall. By reasonably arranging the number, positions and depths of the groove structures, the present application can reduce the number of barrier walls to one without overflowing of the organic barrier layer, thereby effectively reduce the area occupied by the barrier walls and increase the screen ratio of the display panel.

### BRIEF DESCRIPTION OF DRAWINGS

FIG. 1 is a structural diagram of a display panel in a specific embodiment of the present application.

FIG. 2 is a cross-sectional view of a barrier wall of the display panel of FIG. 1 taken along A1-A2 direction before forming a plurality of groove structures.

FIG. 3 is a cross-sectional view of the barrier wall of FIG. 2 taken along A1-A2 direction after forming a plurality of groove structures.

FIG. 4 is a structural diagram of a barrier wall in a specific embodiment of the present application.

FIG. 5 is a structural diagram of a barrier wall in another embodiment of the present application.

FIG. 6 is a top view of the barrier wall of FIG. 5.

FIG. 7 is a cross-sectional view of the display panel of FIG. 2 after forming a thin film encapsulation structure.

FIG. 8 is a top view of a barrier wall in another embodiment of the present application.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

Referring to FIG. 1, FIG. 1 is a structural diagram of a display panel in an embodiment of the present application. The display panel includes a display area 110, a non-display area 120 surrounding the display area 110, and a bending area 130 located below the non-display area 120. The non-display area 120 includes a first barrier wall 121 and a second barrier wall 122 surrounding the first barrier wall 121.

In order to reduce an area of the barrier wall, only one layer, that is, a third barrier wall 410, is disposed on the barrier wall above the bending area 130. In order to enhance a blocking effect of the third barrier wall 410, a structure of the third barrier wall 410 is improved.

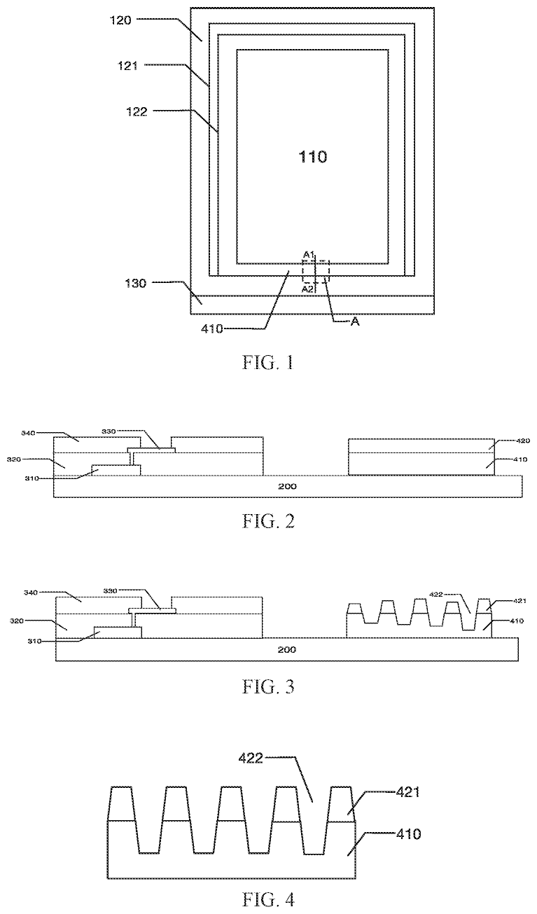

Referring to FIG. 2, FIG. 3 and FIG. 7. FIG. 2 is a cross-sectional view of a barrier wall of the display panel of FIG. 1 taken along A1-A2 direction before forming a plurality of groove structures. FIG. 3 is a cross-sectional view of the barrier wall of FIG. 2 taken along A1-A2 direction after forming a plurality of groove structures. FIG. 7 is a cross-sectional view of the display panel of FIG. 2 after forming a thin film encapsulation structure.

In the present application, the display panel includes a flexible substrate 200, and the display area 110 and the non-display area 120 are both located on the flexible substrate 200. The display area 110 includes a thin film transistor layer 310, a planarization layer 320 covering the thin film transistor layer 310, a pixel defining layer 340 on the planarization layer 320, and a plurality of light emitting structures 330 located among the plurality of openings of the pixel defining layer 340.

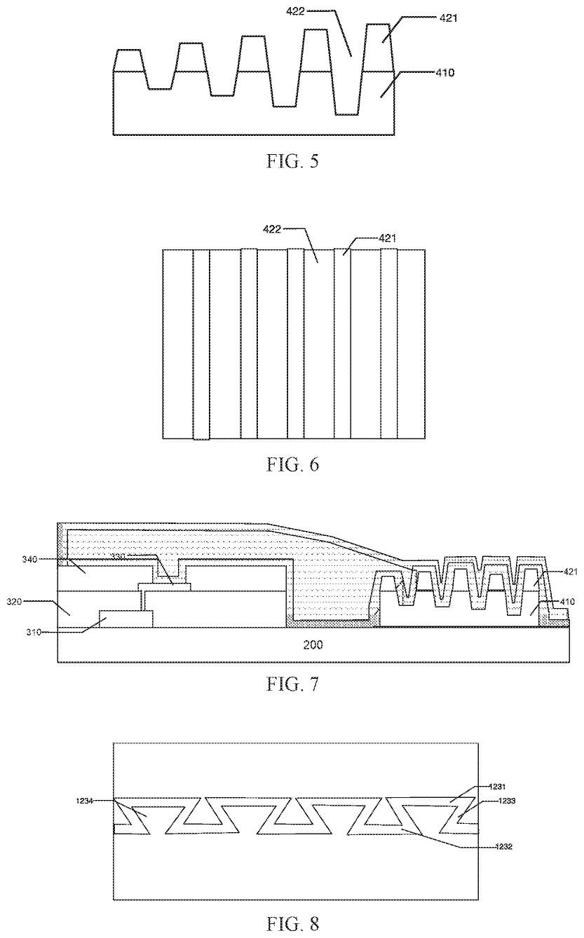

The non-display area 120 includes a barrier wall 410 surrounding the display area 110, and a top of the barrier wall 410 has a plurality of groove structures 422 disposed in parallel. Referring to FIG. 6, an extending direction of the plurality of groove structures 422 is parallel to an extending direction of the barrier wall 410.

A thin film encapsulation structure 500 covers the display area and the non-display area. It can be seen that the groove structure 422 can confine an inorganic film of the thin film encapsulation structure 500 in the groove structures. The organic barrier material is prevented from overflowing, so that a sealing of the organic barrier material can be achieved by a single barrier wall.

The present application will be described in detail below in conjunction with specific embodiments.

Referring to FIG. 7, the barrier wall 410 further includes a plurality of cap structures 421 located on the top of the barrier wall 410 on both sides of the plurality of groove structures.

Referring to FIG. 2 and FIG. 3, the groove structure 422 and the cap structure 421 are formed by the following steps. First forming a first insulating layer 420 on the top of the barrier wall 410, then patterning the first insulating layer 420 to form a plurality of cap structures 421 arranged in parallel. The extending direction of the plurality of cap structures 421 is parallel to the extending direction of the barrier wall 410. Finally, etching the barrier structure 410 by using the cap structure 421 as a mask to form a plurality of parallel groove structures 422.

In this embodiment, the groove structures 422 and the cap structures 421 are simultaneously formed by a same process flow, which can save process cost and simplify the process flow. In this embodiment, in order to enhance an ability of the groove structures 422 to limit the inorganic film, depths of the plurality of groove structures 422 are greater than or equal to a quarter of the height of the barrier wall 410, heights of the cap structure 421 are less than or equal to a minimum depth of the groove structures 422.

In the present application, the plurality of groove structures 422 may have different depths by controlling parameters of the etching process, and the plurality of cap structures 421 have different heights, as shown in FIG. 3. Of course, in other embodiments of the present application, as shown in FIG. 4, the plurality of groove structures 422 have a same depth, and the plurality of cap structures 421 have a same height. A plurality of groove structures 422 and cap structures 421 of the same specification are easier to implement, reducing the process difficulty.

Referring to FIG. 5, in another embodiment of the present application, the a depth of each groove structure 422 is positively related to a distance from the groove structure 422 to the display area 110, a depth of the groove structure 422 closest to the display area 110 is less than a depth of the groove structure 422 furthest from the display area 110. Similarly, a height of each cap structure 421 is also positively related to a distance from the cap structure 421 to the display area 110. A height of the cap structure 421 closest to the display area 110 is less than a height of the cap structure 421 furthest from the display area 110.

In the present application, in order to further enhance the barrier ability of the barrier wall 410, the structure of the barrier wall 410 is further optimized. Referring to FIG. 8, the barrier wall 410 includes a first section, a second section, and a plurality of connecting sections 1233.

The first section comprising a plurality of first subsections 1231 extending along a length direction of the plurality of first sections, wherein first intervals are disposed between two adjacent first subsections. The second section disposed in parallel with the first section, wherein the second section comprises a plurality of second subsections 1232, second intervals are disposed between two adjacent second subsections 1232, positions of the second subsections 1232 correspond to positions of the first intervals, positions of first subsections 1231 correspond to positions of the second intervals.

The plurality of connecting sections 1233 located between the first section and the second section, wherein the connecting sections are used for connecting each of the first subsections 1231 and the two second subsections 1232 adjacent to the first subsection 1231.

The plurality of first subsections 1231 are equal in length, the plurality of first intervals are equal in length, the plurality of second subsections 1232 are equal in length, the plurality of second intervals are equal in length. The length of the plurality of first subsections 1231 is greater than the length of the plurality of second intervals, the length of the plurality of second subsections 1232 is greater than the length of the first interval. A distance between the first section and the second section is greater than or equal to a sum of the widths of the first section and the second section and less than or equal to twice the sum of the widths of the first section and the second section.

In this embodiment, each of the first subsections 1231 and the two connection sections 1233 connected to the first subsection 1231 form a trapezoidal structure. Each of the second subsections 1232 and the two connection sections 1233 connected to the second subsection 1232 form a trapezoidal structure. The trapezoidal structure can generate three barriers to the inorganic film at the barrier wall, thereby greatly improving the barrier capability of the barrier wall.

The present application further provides a method of fabricating a display panel, wherein the method comprises the steps of:

providing a substrate 200 and forming a display area 110 on the substrate 200;

forming a barrier wall 410 surrounding the display area 120;

forming a first insulating layer 420 on a top of the barrier wall 410;

patterning the first insulating layer 420 to form a plurality of cap structures 421 arranged in parallel, an extending direction of the plurality of cap structures 421 is parallel to an extending direction of the barrier wall 410;

etching the barrier wall 410 by using the cap structures 421 as a mask to form a plurality of parallel groove structures 422.

The present application improves a barrier capability of a single barrier wall to the organic encapsulation layer by providing a plurality of groove structures on the top of the barrier wall. By reasonably arranging the number, positions and depths of the groove structures, the present application can reduce the number of barrier walls to one without overflowing of the organic barrier layer, thereby effectively reduce the area occupied by the barrier walls and increase the screen ratio of the display panel.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. A display panel comprising a display area and a barrier wall surrounding the display area, wherein a top of the barrier wall has a plurality of groove structures arranged in parallel, an extending direction of the plurality of groove structures is parallel to an extending direction of the barrier wall;
wherein the barrier wall further comprises a plurality of cap structures located on the top of the barrier wall on both sides of the plurality of groove structures;
wherein depths of the plurality of groove structures are greater than or equal to a quarter of a height of the barrier wall, heights of the cap structures are less than or equal to a minimum depth of the groove structure;
wherein the groove structures have different depths, the cap structures have different heights;
wherein a depth of each groove structure is positively related to a distance from the groove structure to the display area, a depth of the groove structure closest to the display area is less than a depth of the groove structure furthest from the display area.

2. The display panel of claim 1, wherein the barrier wall comprises:
a first section comprising a plurality of first subsections extending along a length direction of the plurality of first sections, wherein first intervals are disposed between two adjacent first subsections;
a second section disposed in parallel with the first section, wherein the second section comprises a plurality of second subsections, second intervals are disposed between two adjacent second subsections, positions of the second subsections correspond to positions of the first intervals, positions of first subsections correspond to positions of the second intervals; and
a plurality of connecting sections located between the first section and the second section, wherein the connecting sections are used for connecting each of the first subsections and the two second subsections adjacent to the first subsection.

3. The display panel according to claim 2, wherein the plurality of first subsections are equal in length, the plurality of first intervals are equal in length, the plurality of second subsections are equal in length, the plurality of second intervals are equal in length.

4. The display panel according to claim 3, wherein the length of the plurality of first subsections is greater than the length of the plurality of second intervals, the length of the plurality of second subsections is greater than the length of the first interval.

5. The display panel according to claim 4, wherein a distance between the first section and the second section is greater than or equal to a sum of the widths of the first section and the second section and less than or equal to twice the sum of the widths of the first section and the second section.

6. A display panel comprising a display area and a barrier wall surrounding the display area, wherein a top of the barrier wall has a plurality of groove structures arranged in parallel, an extending direction of the plurality of groove structures is parallel to an extending direction of the barrier wall.

7. The display panel according to claim 6, wherein the barrier wall further comprises a plurality of cap structures located on top of the barrier wall on both sides of the plurality of groove structures.

8. The display panel according to claim 7, wherein depths of the plurality of groove structures are greater than or equal to a quarter of a height of the barrier wall, heights of the cap structures are less than or equal to a minimum depth of the groove structure.

9. The display panel according to claim 8, wherein the groove structures have different depths, the cap structures have different heights.

10. The display panel according to claim 9, wherein a depth of each groove structure is positively related to a distance from the groove structure to the display area, a depth of the groove structure closest to the display area is less than a depth of the groove structure furthest from the display area.

11. The display panel according to claim 6, wherein the barrier wall comprises:
a first section comprising a plurality of first subsections extending along a length direction of the plurality of first sections, wherein first intervals are disposed between two adjacent first subsections;
a second section disposed in parallel with the first section, wherein the second section comprises a plurality of second subsections, second intervals are disposed between two adjacent second subsections, positions of the second subsections correspond to positions of the first intervals, positions of first subsections correspond to positions of the second intervals; and
a plurality of connecting sections located between the first section and the second section, wherein the connecting sections are used for connecting each of the first subsections and the two second subsections adjacent to the first subsection.

12. The display panel according to claim 11, wherein the plurality of first subsections are equal in length, the plurality of first intervals are equal in length, the plurality of second subsections are equal in length, the plurality of second intervals are equal in length.

13. The display panel according to claim 12, wherein the length of the plurality of first subsections is greater than the length of the plurality of second intervals, the length of the plurality of second subsections is greater than the length of the first interval.

14. The display panel according to claim 11, wherein a distance between the first section and the second section is greater than or equal to a sum of the widths of the first section and the second section and less than or equal to twice the sum of the widths of the first section and the second section.

15. A method of fabricating a display panel, wherein the method comprises the steps of:
providing a substrate and forming a display area on the substrate;
forming a barrier wall surrounding the display area;
forming a first insulating layer on a top of the barrier wall;
patterning the first insulating layer to form a plurality of cap structures arranged in parallel, an extending direction of the plurality of cap structures is parallel to an extending direction of the barrier wall;
etching the barrier wall by using the cap structures as a mask to form a plurality of parallel groove structures.
